(19) United States
(12) Patent Application Publication
(10) Pub. No.: US 2006/0098767 A1
(43) Pub. Date: May 11, 2006

(54) Wireless receiver with anti-jamming

(75) Inventors: Ephraim Zehavi, Haifa (IL); Ido Bettesh, Haifa (IL)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Mobilian to Intel

(21) Appl. No.: 11/266,051

(22) Filed: Nov. 2, 2005

Related U.S. Application Data
(63) Continuation of application No. 10/094,028, filed on Mar. 8, 2002.
(60) Provisional application No. 60/274,499, filed on Mar. 9, 2001.
(60) Provisional application No. 60/297,862, filed on Jun. 13, 2001.

(51) Int. Cl. H03D 1/04; H04L 27/14

(52) U.S. Cl. 375/346; 375/334

(57) ABSTRACT

An embodiment of the present invention provides a method for communicating data in the presence of jamming interference, comprising transmitting a first signal carrying the data from a transmitter to a receiver at a data transmission rate, determining at the receiver that the first signal has been corrupted by the jamming interference, sending a reply from the receiver to the transmitter, indicating that the first signal was corrupted, responsive to the reply, transmitting a second signal carrying the data from the transmitter to the receiver substantially without back-off of the transmission rate, and processing the first and second signals at the receiver to recover the data therefrom.

### CROSS-REFERENCE TO RELATED APPLICATIONS

This application claims the benefit of U.S. Provisional Patent Applications No. 60/274,499, filed Mar. 9, 2001, and No. 60/297,862, filed Jun. 13, 2001. Both of these provisional applications are incorporated herein by reference.

### FIELD OF THE INVENTION

The present invention relates generally to wireless data communication networks, and specifically to receivers for wireless local area networks that must operate in the presence of jamming.

### BACKGROUND OF THE INVENTION

Wireless local area networks (WLANs) are gaining in popularity, and new applications are being developed. The original WLAN standards, such as “Bluetooth” and IEEE 802.11, were designed to enable communications at 1-2 Mbps in a band around 2.4 GHz. More recently, IEEE working groups have defined the 802.11a and 802.11b extensions to the original standard, in order to enable higher data rates. The 802.11a standard (including Annex G of the standard) envisions data rates over 20 Mbps over short distances in the 2.4 and 5.5 GHz bands, using Coded Orthogonal Frequency Division Modulation (COFDM). The COFDM system uses multiple subcarriers, which are modulated using phase shift keying (PSK) or quadrature amplitude modulation (QAM). The 802.11b standard defines data rates up to 11 Mbps in the 2.4 GHz band using Quadrature PSK (QPSK) or 8-ary PSK (8PSK). These modulation schemes are further described in the IEEE 802.11 standards, which are incorporated herein by reference.

Wireless modems are sensitive to unintentional jamming by high-power narrowband signals in the communication band of the desired signal. Jamming is particularly problematic in the 2.4 and 5.5 GHz bands, which have been set aside by the Federal Communications Commission (FCC) for unlicensed use. Modems operating in this range under the 802.11 standards must typically deal with strong jamming signals generated by other communication devices such as cordless telephones and Bluetooth transmitters. Receivers known in the art generally use adaptive notch filters to remove such interference. Techniques of adaptive filtering, however, suffer from slow convergence and lack the capability to deal with transient in-band jamming. Bluetooth signals, for example, hop to a new frequency in the 2.4 GHz band once every microsecond, in a hop pattern that appears random to a non-Bluetooth device. Even using very fast adaptation, every such hop in an adaptive filtering system will generally cause a burst of errors in an COFDM or M-PSK receiver.

### SUMMARY OF THE INVENTION

In accordance with one aspect of the present invention, a wireless receiver applies one or more of a number of novel approaches to estimate and remove jamming interference from received Frequency Division Modulation (FDM) signals. These approaches include the following:
Detecting the frequencies at which jamming occurs, and erasing these frequencies from the processed signal before demodulating the signal to recover the data. Typically, convolutional coding is applied to the transmitted signal, and the signal is demodulated using a Viterbi decoder in the receiver. In an exemplary embodiment, certain frequencies can be erased or given reduced weights during the decoding process in a manner that permits the signal to be decoded based on the remaining frequencies. Alternatively, the principle of erasing jammed frequencies can also be applied using other demodulation techniques, as are known in the art.
Detecting the phase of the jamming signal, using a phase detector, and then reconstructing the jamming signal so as to cancel it from the processed signal. The phase detector operates most effectively in this manner when the jamming signal is strong, and this method is therefore preferably used when the strength of the jamming signal prevents sufficiently complete removal solely through the preceding approach of frequency “erasure.” Due to factors such as the finite length of the time window used in transforming the received signal to the frequency domain for demodulation, the effects of a strong jamming signal in a narrow band may be felt over a much wider range of frequencies in the receiver. Cancellation of the jamming signal before transformation to the frequency domain can help to overcome this problem.
Demodulating the jamming signal, when the method of modulation used in the jamming signal is known (for example, Frequency Shift Keying—FSK—modulation used for Bluetooth signals). The receiver can then accurately reconstruct the jamming signal in order to remove it from the processed signal. This approach is preferably used under the strongest jamming conditions.
Active digital or analog cancellation of the jamming signal. This approach is possible when the jamming signal is “cooperative,” for example, a signal generated by a Bluetooth transmitter collocated with a FDM receiver, so that the transmitter output is known to the receiver.

A receiver configured in accordance with the present invention may include an anti-jamming controller, which monitors the jamming characteristics, and selects one of the above methods depending on the level and nature of jamming. Several jamming signals may be monitored and dealt with simultaneously in this manner. Alternatively, the receiver may be designed to implement only one these anti-jamming methods, against a single jamming signal or multiple jamming signals. If the jamming is sufficiently weak, the controller turns off the anti-jamming function.

In certain embodiments of the present invention, the phase detector used in determining the phase of the jamming signal comprises a phase-locked loop (PLL), preferably a digitally-implemented PLL. A buffer typically stores one or more blocks of samples of the incoming signal while the phase detector and jamming cancellation circuitry operates on the samples. This block-oriented mode of operation allows the PLL to be operated in non-causal fashion, running both forward and backward in time, in order to accurately estimate transitions and other parameters of the jamming signal. Alternatively, the phase detector may comprise a filter, such as a finite impulse response (FIR) or infinite impulse response (IIR) filter, with an automatic frequency control (AFC) circuit.

In further exemplary embodiments of the present invention, other techniques are used to improve the anti-jamming performance of a transmitter/receiver pair. In one such exemplary embodiment, when the receiver determines that a packet has been corrupted by jamming but that the packet header may nonetheless enable identification of the identity of the transmitter that sent the packet, the receiver sends a NACK (non-acknowledge) signal to the transmitter. The transmitter, upon receiving the NACK, retransmits the packet without back-off. Additionally or alternatively, an outer code is added to the transmitted data in each packet. Preferably, for the purpose of outer coding, each packet is divided into several code words, with Reed-Solomon codes.

Although the inventors have developed these techniques particularly for use in FDM schemes, such as those specified by IEEE standard 802.11a, the principles of these techniques may also be applied, mutatis mutandis, to processing of signals based on other modulation schemes, such as M-PSK (as specified by the 802.11b standard) and Code Division Multiple Access (CDMA) schemes. These principles may also be applied to different types of narrowband jamming signals with different modulation schemes, such as PSK modulation, QAM modulation or CDMA.

In one aspect, the present invention relates to a receiver capable of receiving a signal carrying data via multiple subcarriers at respective subcarrier frequencies. The receiver includes an anti-jamming (AJ) processor, adapted to assess jamming interference on the subcarrier frequencies and, responsive thereto, to assign respective reliability metrics to the subcarriers. The receiver further includes a demodulator adapted to demodulate the signal using the reliability metrics and thereby recover the data.

In another aspect, the present invention comprises a receiver capable of receiving a signal carrying data in the presence of jamming interference. The receiver includes an anti-jamming (AJ) processor adapted to process the received signal so as to determine a frequency, phase and amplitude of the jamming interference. A jamming cancellation circuit, coupled to the AJ processor, removes the jamming interference from the received signal responsive to the frequency, phase and amplitude determined by the AJ processor. The receiver further includes a demodulator adapted to demodulate the signal after removal of the jamming interference therefrom so as to recover the data.

In yet another aspect, the present invention comprises a method for communicating data in the presence of jamming interference. The method includes transmitting a first signal carrying the data from a transmitter to a receiver at a data transmission rate. If it is determined at the receiver that the first signal has been corrupted by the jamming interference, then a reply is sent from the receiver to the transmitter, indicating such corruption has occurred. In response to the reply, a second signal carrying the data from the transmitter to the receiver is transmitted substantially without back-off of the transmission rate. The first and second signals are then processed at the receiver in order to recover the data therefrom.

The present invention also contemplates a method for processing a received signal carrying data via multiple subcarriers at respective subcarrier frequencies. The method includes assessing jamming interference on the subcarrier frequencies. In response to the assessed interference, respective reliability metrics are assigned to the subcarriers. The signal is then demodulated using the reliability metrics so as to recover the data.

In a further aspect, the present invention relates to a method for recovering data from a signal received in the presence of jamming interference. The method includes processing the received signal so as to determine a frequency, phase and amplitude of the jamming interference. Jamming interference is removed from the received signal responsive to the determined frequency, phase and amplitude. The signal is then demodulated after removal of the jamming interference therefrom so as to recover the data.

The present invention will be more fully understood from the following detailed description of various embodiments thereof, taken together with the drawings in which:

### BRIEF DESCRIPTION OF THE DRAWINGS

FIG. 1 is a block diagram that schematically illustrates a wireless data receiver, in accordance with an exemplary embodiment of the present invention;

FIG. 2 is a block diagram that schematically illustrates an anti-jamming processor, in accordance with an exemplary embodiment of the present invention;

FIG. 3 is a block diagram that schematically illustrates a phase detector for determining the phase of a jamming signal, in accordance with an preferred embodiment of the present invention;

FIG. 4 is a block diagram that schematically illustrates circuitry for demodulating and reconstructing a jamming signal, in accordance with an exemplary embodiment of the present invention;

FIG. 5 is a flow chart that schematically illustrates a method for removing jamming interference from a signal received by a modem, in accordance with an exemplary embodiment of the present invention;

FIGS. 6A, 6B and 6C are timing diagrams that schematically illustrate processing of signals by a modem to removing jamming interference from the signal, in accordance with an exemplary embodiment of the present invention;

FIG. 7 is a block diagram that schematically illustrates circuitry for digital active cancellation of a jamming signal, in accordance with an exemplary embodiment of the present invention; and

FIG. 8 is a flow chart that schematically illustrates a method for transmitting and receiving data packets in the presence of jamming, in accordance with an exemplary embodiment of the present invention.

### DETAILED DESCRIPTION OF PREFERRED EMBODIMENTS

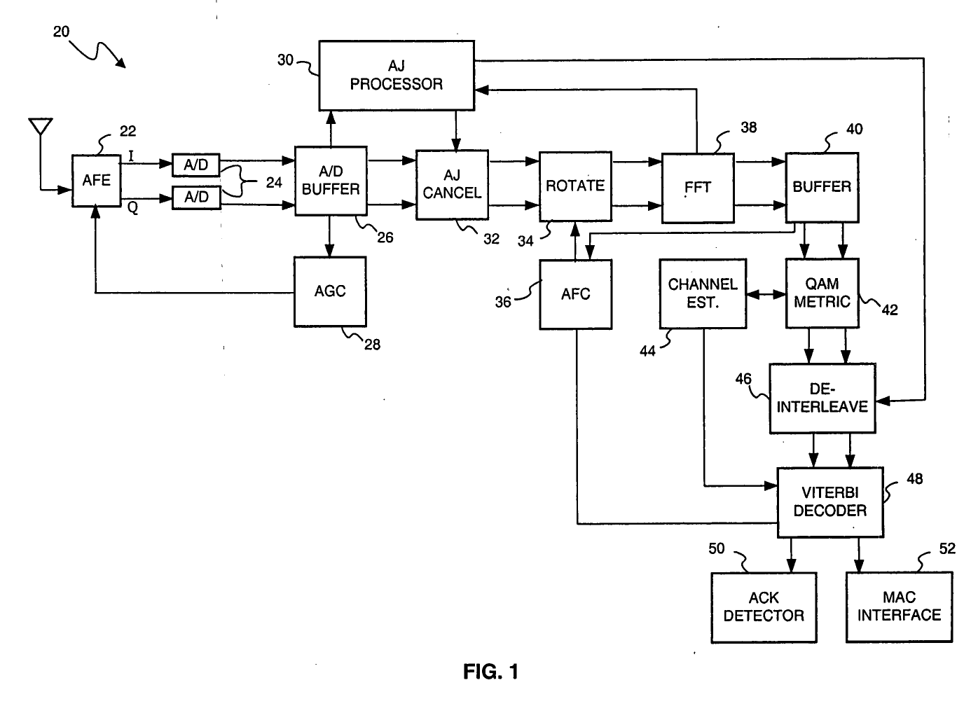

FIG. 1 is a block diagram that schematically illustrates a wireless receiver 20, in accordance with an exemplary embodiment of the present invention. In the description that follows, receiver 20 is assumed to be part of a modem used in a wireless LAN (WLAN), operating in accordance with an COFDM modulation scheme. Exemplary schemes of this sort are those put forth by IEEE standard 802.11a, including Annex G of the standard, as noted in the Background of the Invention. The WLAN environment is assumed to be noisy and, in particular, subject to jamming interference from a variety of possible sources, such as signals generated by Bluetooth transmitters. Although the elements of receiver 20 are shown and described in terms of separate functional blocks, it will be apparent to those skilled in the art that many or even all of these blocks may be implemented in a single integrated circuit chip or in a set of such chips. Additionally or alternatively, the digital processing functions described hereinbelow may be implemented in software running on a suitable microprocessor.

Receiver 20 comprises an analog front end (AFE) 22, which performs initial analog processing on signals received over the air, as is known in the art. The AFE filters, amplifies, and splits the signals into in-phase (I) and quadrature (Q) parts, which are digitized by analog/digital (A/D) converters 24. Preferably, the A/D converters sample the incoming signal at a rate of 44 Msps (million samples/sec). The digitized signals are then held in an A/D buffer 26, which is preferably configured to hold samples from two successive time segments, corresponding to two successive COFDM symbols. In terms of the 802.11a standard, this means that the buffer should hold two I/Q vectors of samples, each comprising 44*80*2 samples.

Preferably, an automatic gain control (AGC) circuit 28 reads the digitized samples in buffer 26 and analyzes the signals to control the gain of AFE 22, as is known in the art. A preamble detector (not shown) also uses the data in the buffer to detect the beginning of a data packet and thereby control other elements of receiver 20. The functions of the preamble detector are beyond the scope of the present patent application and are therefore omitted from the figures for the sake of simplicity.

An anti-jamming (AJ) processor 30 reads the data in A/D buffer 26, and uses these data to reduce or eliminate the effects of jamming signals in receiver 20. Preferably, processor 30 implements a range of different anti-jamming measures, depending on the strength and nature of the jamming signals, as described in detail hereinbelow. By holding two symbols in succession, buffer 26 allows processor 30 to analyze the incoming samples in both forward and reverse temporal directions, so as to accurately determine the phase, frequency and onset/termination of any jamming signals. When the jamming signal is strong, processor 30 reconstructs the signal and applies an AJ canceling block 32 to subtract the reconstructed jamming signal from the samples in buffer 26. Additionally or alternatively, processor 30 may indicate that certain frequencies in the input signal should be erased, or at least treated as unreliable, when the signals are decoded.

Following jamming cancellation, the I/Q samples are frequency-corrected by a phase rotator 34, under the control of an automatic frequency control (AFC) circuit 36. Each symbol is then converted to the frequency domain, preferably by a Fast Fourier Transform (FFT) processor 38. The FFT output is held in a buffer 40, which provides input to AFC circuit 36, as is known in the art. The FFT results are also used by AJ processor 30 in determining the frequencies of narrowband jamming signals. In the case of narrowband jammers such as a Bluetooth signal, the jamming signals typically appear as sharp peaks in the spectrum of the COFDM signals.

Based on the FFT results, a metric quantization block 42 assigns a QAM metric to each QAM symbol of the COFDM signal. The QAM metric provides an estimate of the received QAM symbol that is utilized during the decoding process described below. In addition, a channel estimator 44 generates a channel estimate by approximating the phase shift and gain applied to each subcarrier by the communication channel over which the signals are received. Assuming that the symbols were interleaved by the transmitter, a de-interleaver 46 is used to reverse the interleaving. The resultant stream of QAM metrics is then input to a decoder 48, typically a Viterbi decoder, along with corresponding channel estimates. Subject to the anti-jamming processing described hereinafter, the decoder 48 then regenerates the transmitted bitstream on the basis of this estimated symbol and channel information.

In accordance with the invention, when channel estimator 44 has determined that certain frequencies have been corrupted by jamming, it indicates to decoder 48 that the QAM metrics of the corresponding subcarriers should be assigned a low reliability or ignored altogether in the decoding process. The reliability of the subcarriers is typically represented by respective reliability metrics applied by the decoder. The nature of FDM signal transmission with convolutional coding, together with Viterbi decoding, makes it possible to drop certain carriers at the decoding stage without losing data in the bitstream.

The bitstream output of decoder 48 is used in higher-level functions of receiver 20, including an ACK (acknowledgment) detector 50 and a MAC (media access control) interface 52, as are known in the art. The decoder output is also used by channel estimator 44 and by AFC circuit 36. For the purposes of AFC, the bitstream output of decoder 48 is re-encoded, following a short chain-back and interleaving process, and is compared to the samples stored in buffer 40 in order to determine the frequency correction to be applied by rotator 34.

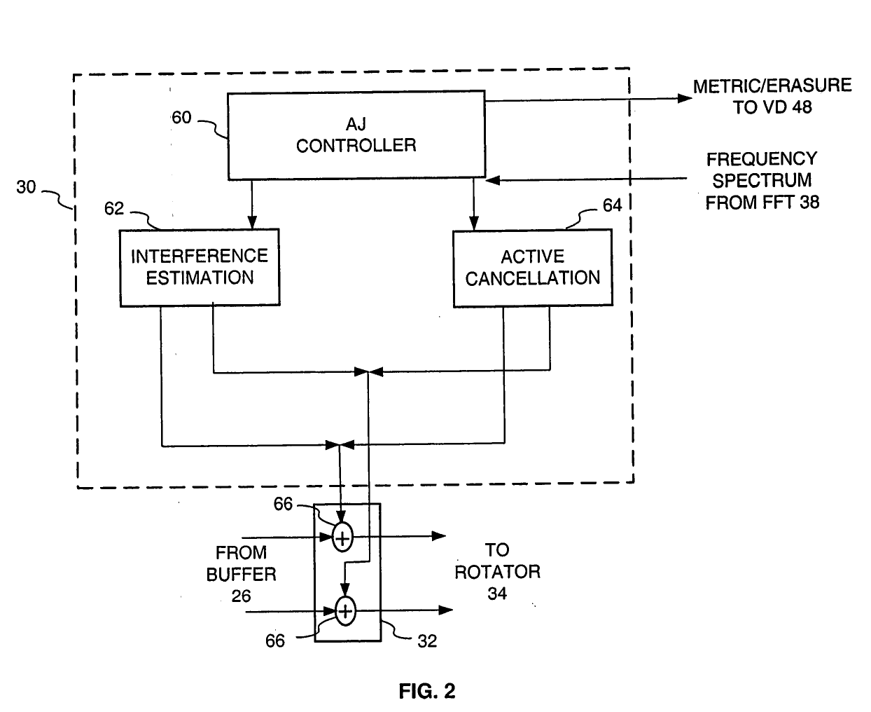

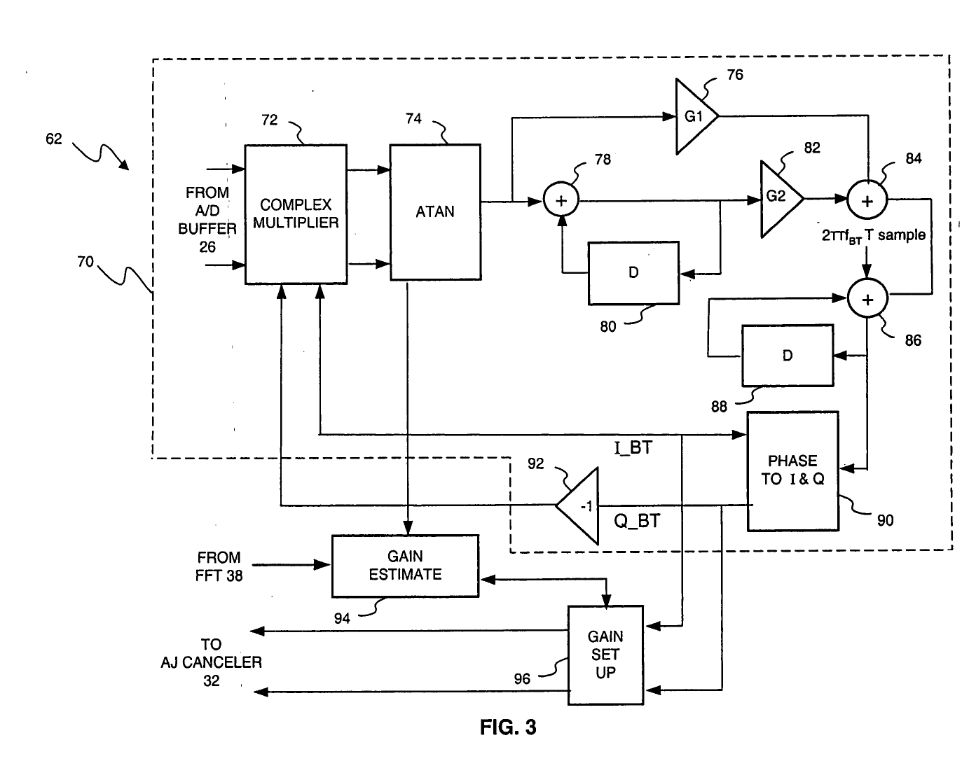

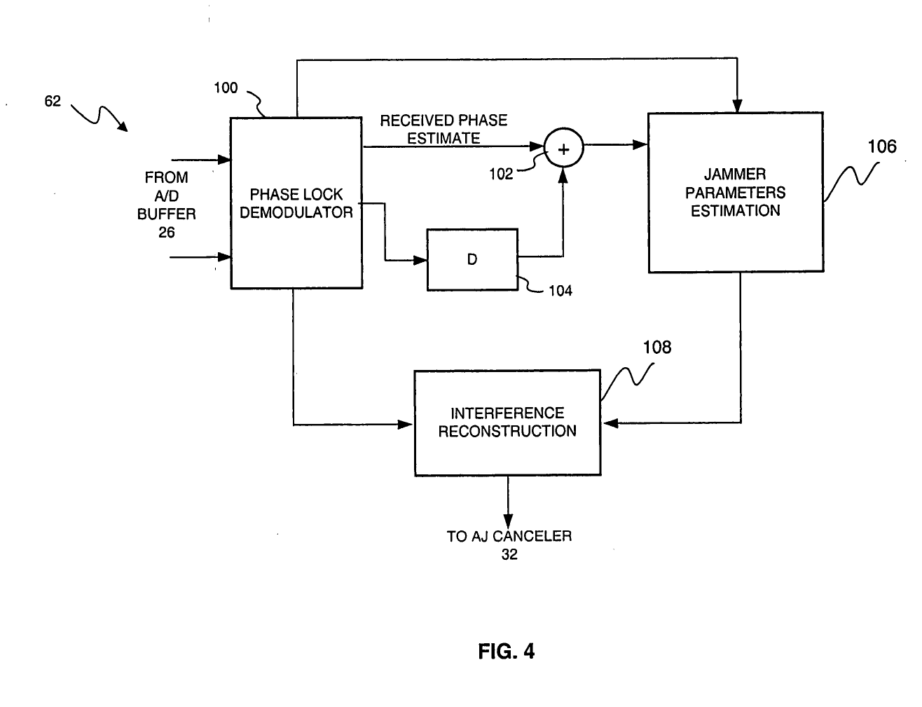

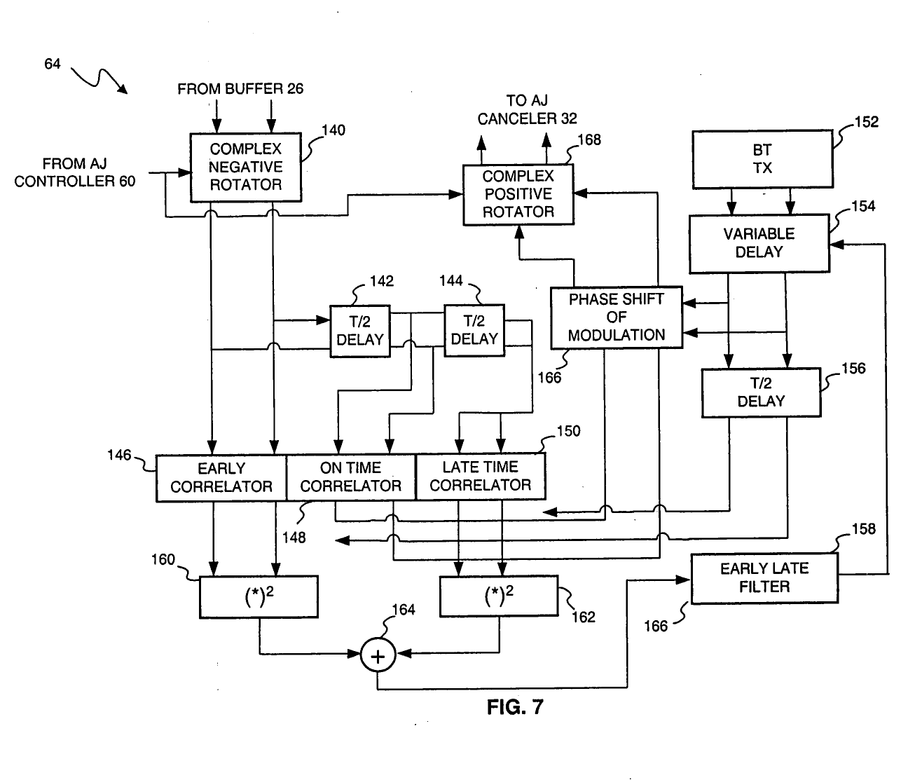

FIG. 2 is a block diagram showing details of AJ processor 30, in accordance with an exemplary embodiment of the present invention. As pictured in FIG. 2 and described hereinbelow, processor 30 provides a range of different AJ measures, which are implemented selectively by an AJ controller 60, depending on the strength and other characteristics of the jamming signal. The measures are typically selected based on the following alternative jamming scenarios:
1. Jamming signal absent or too weak to detect. In this case, each subcarrier channel is assigned a reliability metric based on the quality of reception at the corresponding frequency. The metric is applied by decoder 48.
2. Jamming signal is detectable, but not strong enough to reconstruct its phase and other parameters. The subcarrier channels that are jammed are assigned an erasure metric. The erasure metric is typically a reliability measure that, when applied to jammed channels, is so low as to cause decoder 48 to effectively ignore such channels. Other subcarriers receive reliability metrics based on the quality of reception, as described above.
3. Jamming signal is strong enough to allow reconstruction. In this case, an interference estimation circuit 62 reconstructs the phase and other parameters of the jamming signal, while the input signal is held in buffer 26. Details of circuit 62 are shown in FIGS. 3 and 4. The reconstructed jamming signal is subtracted from the input signal by adders 66 in AJ canceling block 32. The reliability or erasure metrics of the subcarrier channels are preferably assigned or adjusted following AJ cancellation.
4. Jamming signal is strong enough to allow reconstruction, and its modulation scheme is known. This will be the case, for example, when the jamming is known to be caused by FSK signals, as are generated by Bluetooth transmitters. In this case, circuit 62 can not only estimate the phase of the jamming signal, but can actually demodulate the signal and derive other signal parameters, such as modulation index and timing. The reconstructed jamming signal is subtracted from the signal in buffer 26, and the subcarrier metrics are assigned, as described above.
5. Jamming signal is generated by a known source, such as a Bluetooth transmitter collocated with receiver 20. For example, it is expected that some data communication devices will be configured with both a Bluetooth modem for low-rate communications and an 802.11-compliant modem for higher-rate transmissions. In this case, a digital active cancellation circuit 64 can receive an input from the Bluetooth transmitter (or other known jamming source), and can use this input to determine precisely the anti-jamming correction to be applied by AJ canceling block 32. Details of circuit 64 are shown in FIG. 7.

AJ processor 30 may be configured to apply all of the above measures, or only a subset of them, depending on the expected jamming environment in which receiver 20 must operate and other factors, such as cost of the modem or other device in which the receiver is used. When multiple jamming signals are present simultaneously at different frequencies, AJ controller 60 may decide to apply different measures against different signals, depending on the jamming signals strengths and modulation characteristics. In order to reconstruct multiple jamming signals in real time, AJ processor 30 will typically comprise multiple interference estimation and cancellation circuits or modules. Although the possibility of erasing or reducing the reliability measure of jammed subcarriers (scenario 2 above) is applicable primarily to FDM receivers, the remaining alternatives for reconstructing and canceling the jamming signal at the receiver can be applied in receivers using other modulation schemes, as well, such as M-PSK modulation.

FIG. 3 is a block diagram that schematically shows details of interference estimation circuit 62, in accordance with an exemplary embodiment of the present invention. In this embodiment, circuit 62 is based on a second-order digital phase-locked loop (PLL) 70, which determines the phase of the jamming signal. Alternatively, other types of PLLs may be used, as described, for example, by Lindsey and Chie, in “A Survey of Digital Phase-Locked Loops,” Proceedings of the IEEE 69 (1981), pp. 410-431, which is incorporated herein by reference. Further alternatively, other means known in the art may be used to determine the phase of the jamming signal, such as a suitable finite impulse response (FIR) filter or an infinite impulse response (IIR) filter.

PLL 70 generates a waveform s(n), given by s(n)=K exp {j(\hat{Φ}(n)+Φ₀}, wherein n is the sample index, given by t=nTₛₐₘₚₗₑ, and \hat{Φ}(n) is the estimated phase of the jamming signal at sample n. A complex multiplier 72 multiplies samples r(n) from buffer 26, having phase Φ(n), by s*(n), to generate an error signal:
e(n)=r(n)•s*(n)=K′ exp {j(Φ(n)−\hat{Φ}(n)} (1)
An arctangent converter 74 converts the I and Q components of e(n) to a phase error:
θₑ(n)=arctan (r(n)•s*(n)) (2)

The phase error is fed to a first amplifier 76, with gain G₁, and to a second amplifier 82, with gain G₂, via an adder 78 and an accumulator 80. Computation of the appropriate gain values is described in an Appendix to this specification. The outputs of the amplifiers are summed by an adder 84, and the result is summed by another adder 86 with the contents of an accumulator 88 and with a constant increment 2πf_{BT}Tₛₐₘₚₗₑ. Here f_{BT} is the frequency of the jamming signal, determined based on the output of FFT processor 38. The label “BT” is used to denote that the jamming signal is generated by a Bluetooth transmitter, by way of example, but other narrowband jamming signals can be treated in like manner. The phase error stored in accumulator 88 is converted to I/Q form, by a converter 90, to generate the new value of the signal s(n). This signal is conjugated using an inverter 92, and is then input to complex multiplier 72.

Assuming that PLL 70 has sufficient bandwidth to track changes in the jamming signal, the waveform s(n) provides a consistent reconstruction of the jamming signal. To determine the correct amplitude K to apply to the waveform, the phase error determined by arctangent converter 74 and the amplitude of the jamming frequency components from FFT processor 38 are fed to a gain estimator 94. The estimator preferably uses a lookup table to determine the optimal gain value, which is applied by a gain set-up block 96 to the I and Q components of s(n) that are output by converter 90. The result is a reconstruction of the phase and amplitude of the jamming signal, which is then subtracted by AJ canceling block 32 from the input signal in buffer 26.

FIG. 4 is a block diagram that schematically illustrates details of interference estimation circuit 62, in accordance with another preferred embodiment of the present invention. Here it is assumed that the modulation scheme of the jamming signal is known, allowing the jamming parameters to be accurately estimated by actually demodulating the jamming signal. In this embodiment, too, circuit 62 comprises a phase lock demodulator 100, which is preferably similar in design and operation to PLL 70, as described above. The phase estimate of the jamming signal is smoothed by low-pass filtering with an adder 102 and a delay stage 104. Based on the phase estimate, a parameter estimation block 106 determines other parameters needed to reconstruct the jamming signal, including its modulation index k and its start and stop times. An interference reconstruction block 108 uses the signal phase and the other parameters provided by block 106 to generate the reconstructed jamming signal output s(t).

For the specific example of a Bluetooth jamming signal, with Gaussian FSK (GFSK) modulation, the modulated jamming signal can be represented as:

$$v ( t ) = \sqrt{\frac{2 E}{T}} exp \{ j ( Φ ( t ) + {Φ}_{0} ) \} \qquad ( 3 )$$

Here E is the signal energy, and T is the symbol period (1 μs for Bluetooth signals). The continuous phase of v(t) is given by:

$$Φ ( t ) = ω t + 2 π k {\int }_{- ∞}^{t} m ( η ) ⅆ η + θ \qquad ( 4 )$$

wherein m(t) is the modulating signal, k is the modulation index, ω is the center frequency of the Bluetooth signal, and θ is the random phase of the Bluetooth signal.

In Bluetooth GFSK, the modulating signal is the result of filtering a NRZ (non-return to zero) sequence of the input data bits with a Gaussian filter whose time impulse response is:

$${h}_{G} ( t ) = \frac{\sqrt{π}}{α} exp ( \frac{- {π}^{2}}{{α}^{2}} {t}^{2} ) , α = \frac{\sqrt{2 ln 2}}{B} \qquad ( 5 )$$

where B is the 3 dB bandwidth of Gaussian filter. The modulating signal can then be expressed as:

$$m ( {kT}_{Sample} ) = {\sum }_{n = - ∞}^{∞} x ( ( k - n ) {T}_{Sample} ) {h}_{G} ( {nT}_{Sample} ) \qquad ( 6 )$$

wherein x(nT_{Sample}) is the sampled NRZ input signal. In an exemplary implementation of the receiver 20, the A/D converters 24 operate to sample the NRZ input signal at the rate of 44 Msps.

Given the phase information and signal parameters determined by blocks 100 and 106, the estimated jamming signal reconstructed by block 108 will have a complex envelope of the form:

$$s ( t ) = K exp \{ j ( \hat{Φ} ( t ) + {Φ}_{0} ) \} = K exp \{ j {\sum }_{- {n}_{0}}^{{NT}_{s}} ( {h}_{G} ( n ) * {θ}_{e} ( n ) ) \} \qquad ( 7 )$$

where Tₛ is used for brevity to denote Tₛₐₘₚₗₑ. It will be seen that s(t) is, essentially, a delayed version of the original jamming signal given by equation (3). Preferably, equation (7) is used to construct a lookup table, which is used by block 108 in reconstructing s(t).

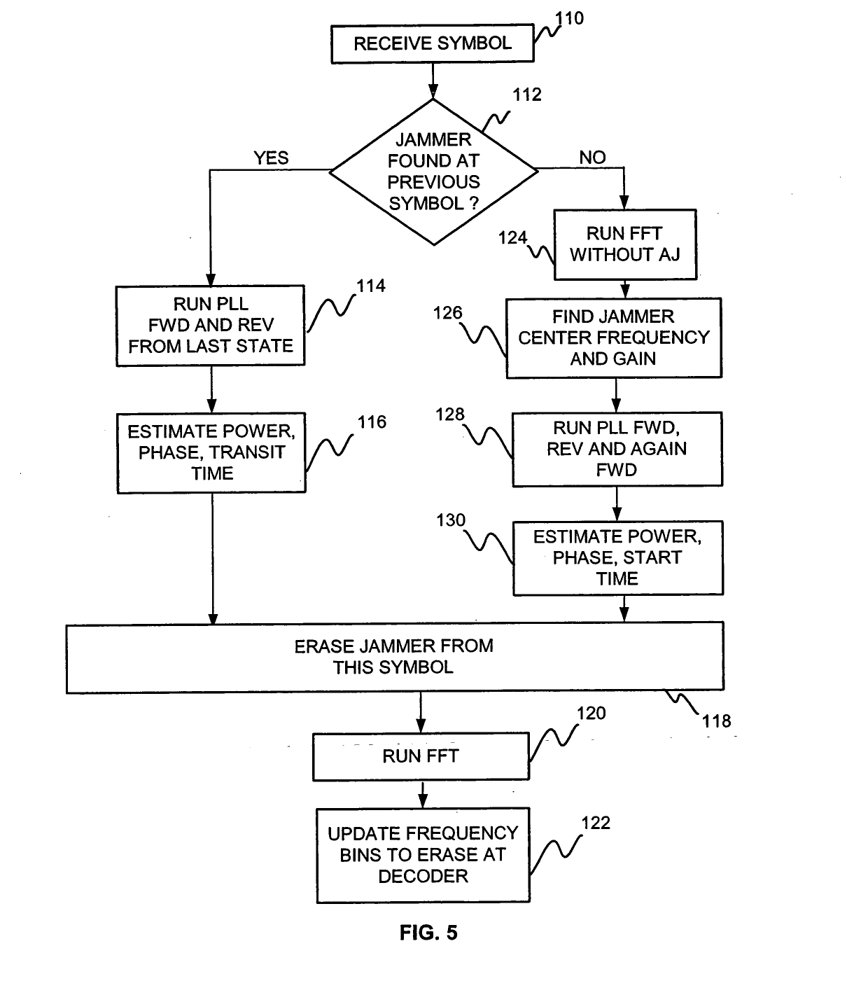

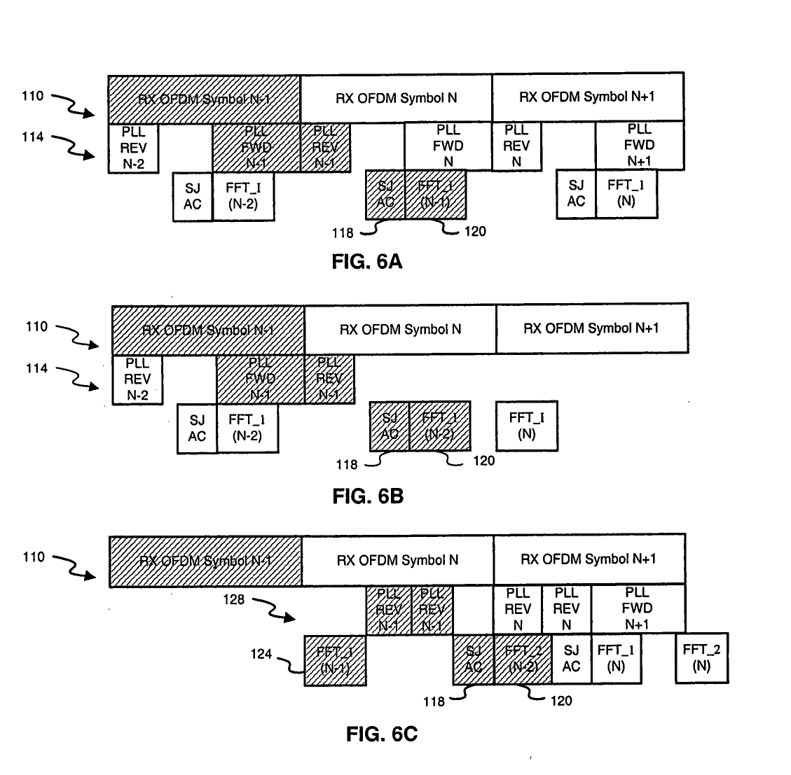

Reference is now made to FIGS. 5 and 6A-C, which schematically illustrate methods for determining the phase of a jamming signal, in accordance with an exemplary embodiment of the present invention. FIG. 5 is a flow chart, showing the steps carried out by AJ processor 30 and other elements of receiver 20 in estimating parameters of the jamming signal. FIGS. 6A-C are timing diagrams, showing the timing of processing stages involved in the phase estimation methods of FIG. 5. FIG. 6A shows the processing stages involved when a jamming signal was present during the preceding COFDM symbol received by receiver 20 and continues through the present symbol; FIG. 6B shows the stages when a jamming signal present during the preceding COFDM symbol terminates at the present symbol; and FIG. 6C shows the stages when a jamming signal is detected initially during the present symbol, without its having been detected at the preceding symbol.

The methods illustrated by these figures take advantage of the block-oriented processing structure of receiver 20. In accordance with this structure, during the time a block of samples is stored in buffer 26, AJ processor 30 can run a phase detector on the samples at least twice—once in a forward time direction, and once in reverse. This forward/backward operation is advantageous in improving the phase detection performance of interference estimation circuit 62, including removal possible bias and phase distortion that can accumulate when conventional unidirectional phase estimation is used. It is particularly useful in finding start and stop times of the jamming. In the description that follows, reference is made to PLL 70 as an example of a phase detector than can be run in a bi-directional manner, but the methods of FIGS. 5 and 6A-C can similarly be applied using phase detectors of other types.

The method of FIG. 5 is initiated each time a block of samples corresponding to a new COFDM symbol is received in buffer 26, at a symbol reception step 110. This new symbol is referred to in FIGS. 6A-6C as COFDM Symbol N-1. The subsequent steps taken by AJ processor 30 depend on whether or not a jamming signal was detected at the previous symbol, as determined at a previous symbol status step 112. If a jamming signal was detected at the previous symbol, PLL 70 runs over the samples in both forward and reverse directions, at a PLL running step 114. For efficient convergence of the PLL, the jamming signal frequency is held at the same value as it had at the preceding symbol, and the initial phase values in accumulators 80 and 88 are also set to the values determined at the conclusion of processing of the preceding symbol. After running PLL 70, the power and phase of the jamming signal are estimated, as described above, at an estimation step 116. If the jamming signal terminates during Symbol N-1 (FIG. 6B), the transit time (i.e., the identification of the sample during the symbol interval at which the jamming terminated) is also estimated.

Based on the power and phase estimates determined at step 116, the jamming signal is reconstructed and subtracted out of the current block of samples by AJ cancellation block 32, at a jamming erasure step 118. After subtraction of the jamming signal and frequency correction by rotator 34, FFT processor 38 operates to transform the symbol to the frequency domain, at a FFT step 120. AJ controller 60 checks the frequency spectrum of the symbol to confirm the existence and removal of the jamming signal, as well as to determine the residual level of interference at the jamming frequency and in other FDM frequency bins. The AJ controller accordingly issues reliability or erasure metrics for these bins, to be applied by Viterbi decoder 48, at a bin update step 122. To the extent that the jamming terminated during the current symbol, the next symbol is processed assuming, at step 112, that no jamming signal was detected during the preceding symbol. The absence of a jamming signal during the next symbol is preferably verified by the FFT performed on the samples of the next symbol.

When a new jamming signal is detected in the current symbol at step 112, without the jamming signal having been present in the previous symbol, the frequency and amplitude of the new jamming signal must be estimated before further processing can take place. These estimates are made by running a FFT on the raw samples in buffer 26, at a preliminary FFT step 124. Based on the FFT spectrum, the center frequency and gain of the jamming signal are found, at a frequency determination step 126. Using this information, PLL 70 is run on the samples of the current symbol in a forward direction, then in reverse, and then forward again, at a PLL rerunning step 128. The results of step 128 are used to estimate the power, phase and start time of the jamming signal during the current symbol, at a start estimation step 130.

The estimated parameters of the jamming signal are used to correct the COFDM samples at step 118. The FFT performed on the corrected samples at step 120 is, in this case, the second FFT performed on the samples of the current symbol. As in the previous case, the FFT enables AJ controller to confirm the jamming frequency (to be used in processing the next symbol, as well) and to determine the metrics to be passed to decoder 48. Because of the delay in carrying out the second FFT at step 120, as exemplified by FIG. 6C, PLL 70 is preferably run on the next block of samples first in the reverse direction, and only afterwards in the forward direction.

FIG. 7 is a block diagram that schematically shows details of active cancellation block 64 (FIG. 2), in accordance with an exemplary embodiment of the present invention. As noted above, this block is used when there is an actual link or similar cooperative relationship established between receiver 20 and a source of jamming interference, such as a Bluetooth transmitter 152 collocated with the receiver.

In order to cancel the Bluetooth jamming signal out of the samples of the COFDM symbol, the samples from buffer 26 are input to a complex negative rotator 140. In operation, the negative rotator 140 functions to frequency align the Bluetooth jamming signal with the baseband Bluetooth transmit signal in order to facilitate establishment of time alignment therebetween. Delay blocks 142 and 144 apply successive delays of T/2 to the samples, wherein T is the Bluetooth symbol period. The samples and their delayed counterparts are then input to a bank of correlators 146, 148 and 150 for correlation with delayed versions of the actual signals generated by Bluetooth transmitter 152 provided by a T/2 delay block 156. For purposes of clarity, the output of the T/2 delay block 156 is not explicitly depicted as being separately connected to each correlator 146, 148 and 150. The results of early correlator 146, which operates on the undelayed samples, and of late correlator 150, which operates on the results delayed by T, are input to absolute value blocks 160 and 162, which provide the real square amplitudes of the complex correlation values. The amplitudes are summed together by an adder 164 and provided to early late filter 158.

Meanwhile, the actual signals generated by Bluetooth transmitter 152 are delayed by a variable delay block 154. The length of the delay is determined by an early/late filter 158. The delayed signals are subjected to an additional T/2 delay, by a fixed delay block 156. The delayed signal output from block 154 is combined with the output of on-time correlator 148 by a phase shift determination block 166, to find the phase shift of the modulation of the Bluetooth signal relative to the COFDM symbols. This phase shift is applied to a complex positive rotator 168 in order to generate the reconstructed Bluetooth signal for subtraction from the COFDM samples by AJ cancellation block 32.

Although the preferred embodiments described above make particular reference to FDM schemes, such as those specified by IEEE standard 802.11a, the principles of these techniques may also be applied, mutatis mutandis, to processing of signals based on other modulation schemes, such as M-PSK (as specified by the 802.11b standard) and Code Division Multiple Access (CDMA) schemes. Similarly, although these preferred embodiments deal by way of example with interference caused by Bluetooth transmitters, the methods of the present invention support coexistence of WLANs with multiple narrowband jamming sources with frequency modulation signals. The principles of the present invention may also be applied to other narrowband jammers with different modulation schemes, such as PSK modulation, QAM modulation or CDMA. In such cases, when the modulation scheme of the jamming source is known, interference estimation block 62 and active cancellation block 64 make use of the particular modulation characteristics of the jamming signal, instead of the GFSK characteristics of Bluetooth. Adaptation of the designs shown in FIGS. 4 and 7 to operate with other modulation schemes will be straightforward for those skilled in the art.

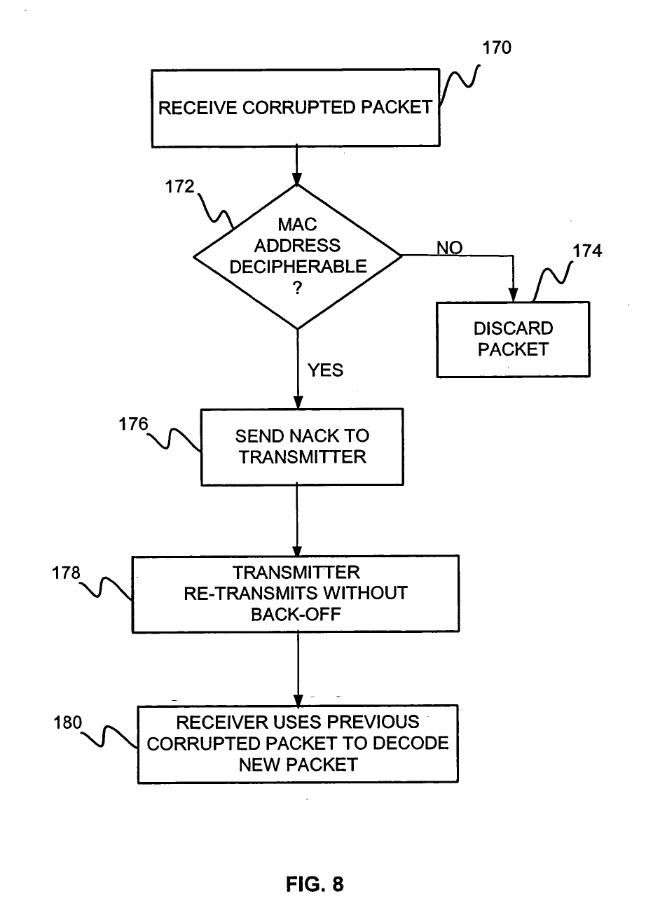

FIG. 8 is a flow chart that schematically illustrates a method for transmitting and receiving packets over a WLAN in the presence of jamming, in accordance with another preferred embodiment of the present invention. This method relies on a novel protocol, which is implemented by a transmitter and receiver in the WLAN independent of any other AJ measures that may be used in the receiver, such as those described with reference to the preceding figures. Present WLAN protocols, such as those specified by IEEE standards 802.11a and 802.11b, provide for the transmitter to back off (i.e., to reduce) its transmission rate when it determines that packets are being lost due to interference. The reduced transmission rate makes it easier for the receiver to decode the packets, but of course, it reduces the throughput of the data link. While this step may be necessary in the presence of broadband interference, it is unnecessarily severe when only narrowband jamming is concerned.

Thus, when the receiver determines that a portion of the data in a packet have been corrupted, at a packet reception step 170, it does not immediately discard the packet, but rather tries to determine the source of the packet and the reason for the data corruption. The receiver attempts to identify the source of the packet by deciphering the source address, typically a MAC address, in the packet header, at an address reading step 172. If the address is indecipherable, the packet is simply discarded, in accordance with existing protocols, at a discard step 174.

On the other hand, if the receiver is able to read the packet source address, and determines that the corruption of the data in the packet was due to jamming, the receiver sends a NACK (non-acknowledge) signal to the transmitter, at a NACK step 176. The NACK signal tells the transmitter to retransmit the packet without back-off, at a retransmission step 178. When the retransmitted packet is received, it may be uncorrupted, particularly if the jamming has abated. On the other hand, if the jamming signal continues, the retransmitted packet may also contain corrupted data, but it is probably a different portion of the data from that which was corrupted in the initial packet. Thus, at a decoding step 180, the receiver decodes the entire contents of the retransmitted packet, with the assistance of the data from the initial packet. In this manner, the jamming interference is overcome, with a less drastic reduction of data throughput than is caused by protocols known in the art.

Other techniques may also be used to improve the throughput of COFDM transmissions in the presence of jamming. For example, the number of subcarrier channels used may be increased from the 64 frequencies provided by the 802.11a standard to 128 frequencies, provided that sufficiently accurate frequency estimation is used to maintain orthogonality between the channels. Alternatively or additionally, an outer code may be added to the transmitted data in each packet, to be used in reconstructing COFDM symbols that are erased due to jamming. Preferably, for the purpose of outer coding, each packet is divided into several code words with Reed-Solomon codes. For this same purpose, repeat transmission of the symbols may be used, at the cost of reducing the maximum data rate. For example, the transmitter may use a 16 QAM, rate 2/3 convolutional code with repetition, in place of the 16 QAM, rate 1/2 code specified by the standard.

It will be appreciated that the preferred embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

### APPENDIX—COMPUTATION OF PLL PARAMETERS

Attention is drawn to the above-referenced Provisional Patent Application No. 60/297,862, which describes computation of various parameters and initial conditions pertinent to operation of the DLL 70 of FIG. 3.

1. A method for communicating data in the presence of jamming interference, comprising:
transmitting a first signal carrying the data from a transmitter to a receiver at a data transmission rate; determining at the receiver that the first signal has been corrupted by the jamming interference;
sending a reply from the receiver to the transmitter, indicating that the first signal was corrupted;
responsive to the reply, transmitting a second signal carrying the data from the transmitter to the receiver substantially without back-off of the transmission rate; and
processing the first and second signals at the receiver to recover the data therefrom.

2. A method according to claim 1, wherein transmitting the first and second signals comprises transmitting data packets.

3. A method according to claim 1, wherein sending the reply comprises processing the corrupted first signal at the receiver so as to identify the transmitter and sending a non-acknowledge reply to the identified transmitter

4. A method according to claim 3, wherein processing the received signal comprises estimating the phase of the jamming interference, and estimating the amplitude of the jamming interference responsive to the phase.

5. A method according to claim 4, wherein estimating the phase comprises feeding the received signal through a phase-locked loop (PLL).

6. A method according to claim 4, wherein jamming interference comprises a modulated signal, and wherein processing the received comprises demodulating the jamming signal so estimate the amplitude thereof.

7. A method according to claim 6, wherein the modulated jamming signal is due to transmission of a Frequency Shift Keyed (FSK) signal in a narrow band, which hops among different frequencies within a wide band of the signal carrying the data, and wherein demodulating the jamming signal comprises demodulating the FSK signal.
